(19) United States
(12) Patent Application Publication
(10) Pub. No.: US 2025/0226306 A1
(43) Pub. Date: Jul. 10, 2025

(54) ELECTRONIC DEVICE

(71) Applicant: Innolux Corporation, Miaoli County (TW)

(72) Inventors: Chia-Ping Tseng, Miaoli County (TW); Ming-Yen Weng, Miaoli County (TW); Chun-Chin Fan, Miaoli County (TW)

(73) Assignee: Innolux Corporation, Miaoli County (TW)

(21) Appl. No.: 18/979,449

(22) Filed: Dec. 12, 2024

Related U.S. Application Data
(60) Provisional application No. 63/619,319, filed on Jan. 10, 2024.

(30) Foreign Application Priority Data
Sep. 26, 2024 (CN) 202411352687.5

(51) Int. Cl. H01L 23/498; H01L 21/48

(52) U.S. Cl. CPC H01L 23/49894; H01L 23/49827; H01L 23/49838; H01L 21/486

(57) ABSTRACT

The present disclosure provides an electronic device including a substrate having a first surface and a second surface opposite to the first surface, a via hole penetrating the substrate and having a sidewall connecting the first surface and the second surface, a buffer layer disposed on the substrate and the sidewall of the through hole, a passivation layer disposed on the buffer layer and at least containing nitrogen, a first conductor layer disposed on the passivation layer, a second conductor layer disposed on the first conductor layer, and an electronic unit disposed on the second conductor layer.

### CROSS-REFERENCE TO RELATED APPLICATION

This application claims the priority benefit of U.S. provisional application Ser. No. 63/619,319, filed on Jan. 10, 2024, and China application serial no. 202411352687.5, filed on Sep. 26, 2024. The entirety of each of the above-mentioned patent applications is hereby incorporated by reference herein and made a part of this specification.

### BACKGROUND

### Technical Field

The present disclosure relates to an electronic device, and particularly relates to an electronic device with good reliability.

### Description of Related Art

In current semiconductor packaging technology, mounting electronic units with different functions on the same substrate is one of means to improve the performance of electronic devices. However, as the sizes of the electronic devices continue to develop towards light, thin, short, and small aspects, and the user's requirements to the performances of the electronic devices continue to increase, the density of the electronic units mounted on the aforementioned substrate is increased as well. This results in a continuous increase in the aspect ratio of the conductive vias penetrating the aforementioned substrate, for example, the aspect ratio may be at least as high as 8 or above. As such, it may be hard for the conductive vias to meet the current or future requirements in terms of the reliability and/or the process time.

### SUMMARY

The present disclosure provides an electronic device in which the buffer layer is disposed on the sidewall of the via hole and the passivation layer, at least containing nitrogen, is disposed on the buffer layer, so that the conductive layer disposed on the passivation layer can be well filled into the via hole without defects caused by the high aspect ratio. For example, there are no voids in the conductive layer (e.g., conductive via) in the via hole that negatively affect its resistivity, thereby improving the reliability of the electronic device.

According to an embodiment of the present disclosure, the electronic device includes a substrate, a via hole, a buffer layer, a passivation layer, a first conductive layer, a second conductive layer, and an electronic unit. The substrate has a first surface and a second surface opposite to the first surface. The via hole penetrates through the substrate and has a sidewall connecting the first surface and the second surface. The buffer layer is disposed on the substrate and the sidewall of the via hole. The passivation layer is disposed on the buffer layer, wherein the passivation layer at least contains nitrogen. The first conductive layer is disposed on the passivation layer. The second conductive layer is disposed on the first conductive layer. The electronic unit is disposed on the second conductive layer.

Based on the above, in the embodiment of the present disclosure, the passivation layer, at least containing nitrogen, is disposed on the buffer layer, so as to prevent the surface oxidation, and thereby the first conductive layer disposed on the passivation layer can be well adhered to the passivation layer. As such, the second conductive layer disposed on the first conductive layer can be well filled into the via hole penetrating through the substrate without defects caused by the high aspect ratio, and thus the reliability of the electronic device can be improved.

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1F are cross-sectional schematic views of a manufacturing method of an electronic device according to an embodiment of the present disclosure.

FIG. 2A is an enlarged view of a conductive via in FIG. 1C according to an embodiment.

FIG. 2B is an enlarged view of a region R1 in FIG. 2A according to an embodiment.

FIG. 2C is an enlarged view of a region R1 in FIG. 2A according to another embodiment.

FIG. 3 to FIG. 8 are enlarged schematic views respectively for the conductive via in FIG. 1C according to different embodiments.

FIG. 9 is a cross-sectional schematic view of an electronic device according to another embodiment of the present disclosure.

FIG. 10 is a cross-sectional schematic view of an electronic device according to yet another embodiment of the present disclosure.

### DESCRIPTION OF THE EMBODIMENTS

The disclosure can be understood with reference to the following detailed description in conjunction with the accompanying drawings. It should be noted that, for ease of understanding by readers and for the concision of the illustration, multiple drawings in the disclosure only depict a part of the package structure, and certain elements in the drawings are not drawn according to actual scale. In addition, the number and size of each element in the drawings are for illustration only, and are not intended to limit the scope of the disclosure. For example, the relative sizes, thicknesses and positions of various layers, regions and/or structures may be reduced or enlarged for clarity.

Certain terms may be used throughout the disclosure and the claims to refer to specific elements. Those skilled in the art will understand that electronic device manufacturers may refer to the same elements by different names. The disclosure does not intend to distinguish between elements that have the same function but have different names. In the following description and claims, the words including “having” and “including” are open-ended words, and thus should be interpreted as meaning “including but not limited to.”

In this disclosure, “one element being disposed on another element” is used for convenience to describe the relative position between the element and the another element, and is not intended to limit the process steps or sequence of the element and the another element.

Directional terms mentioned herein, such as “up,” “down,” “front,” “rear,” “left,” “right,” and the like refer only to the directions of the drawings. Accordingly, the directional terms used are for illustration, and are not intended to limit the disclosure. It should be understood that when an element or film layer is referred to as being “disposed on” or “connected to” another element or film layer, the element or the film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between. In addition, when the element or film layer is referred to as overlapping another element, the element or film layer at least partially overlaps the another element or film layer.

In the text, the terms “about,” “approximately,” “essentially,” or “substantially” usually implies that a value is within 10% of a given value or range, or within 5%, 3%, 2%, 1%, or 0.5% of a given value or range. In addition, the description “a given range from a first value to a second value” or “a given range between a first value and a second value” implies that the given range includes the first value, the second value, and other values in between.

In some embodiments of the disclosure, terms related to bonding and connection, such as “connection,” “interconnection,” and the like, unless otherwise specified, may mean that two structures are in direct contact, or may also mean that two structures are not in direct contact, in which there are other structures provided between these two structures. The terms related to bonding and connection may also include the case where both structures are movable, or both structures are fixed. Furthermore, the terms “electrically connected” or “coupled” includes any direct and indirect means of electrical connection.

In the embodiments provided later, the same or similar reference numerals are used to refer to the same or similar elements, and the descriptions will not be repeated. In addition, as long as the features of the various embodiments do not depart from or conflict with the spirit of the disclosure, the embodiments may be mixed and matched as desired. It is intended that the disclosure covers modifications and variations provided that they fall within the scope of the following claims and their equivalents. That is, in the following embodiments, technical features in several different embodiments may be replaced, reorganized, and mixed to complete other embodiments without departing from the spirit of the disclosure. Moreover, the terms such as “first” and “second” mentioned in the specification or the claims are only used to name different elements or to distinguish different embodiments or scopes, and are not intended to limit the upper or lower limit of the number of the elements, nor are they intended to limit the manufacturing order or disposition order of the elements.

In some embodiments of this disclosure, the thickness, length, and width may be obtained through a measurement using an optical microscope (OM). The thickness or the width may be obtained by measuring from a cross-sectional image in an electron microscope, but is not limited thereto.

In some embodiments of this disclosure, a surface roughness may be obtained by observing the surface undulations at an appropriate and consistent magnification through the electron microscope such as a scanning electron microscope (SEM) or a transmission electron microscope (TEM) and comparing the surface undulations per unit length (e.g., 10 μm). In some embodiments, the peak-to-valley of the surface undulation has a difference in distance by 0.15 μm to 1 μm. The appropriate magnification refers to a magnification that a roughness or an average roughness of at least one surface with at least 10 undulate peaks is observed in the field of view. Each of layers shown in the accompanying drawings of this disclosure may all have rough surfaces. It is worth noting that the rough surfaces of the aforementioned layers may refer to the high and low undulations presented in the cross-sectional view when observing the surfaces of each layer through the electron microscope.

The manufacturing process of the electronic device in this disclosure may be applied, for example, in a wafer-level package (WLP) process or a panel-level package (PLP) process, and may be a chip-first process or a chip-last-RDL-first process. The electronic device described in this disclosure may be applied to power modules, semiconductor package devices, optical communication modules, display devices, light-emitting devices, backlight devices, antenna devices, sensing devices or splicing devices, but is not limited thereto.

The exemplary embodiments of this disclosure are described in the following for example, and the same reference numerals used in the figures and descriptions are represented to the same or similar portions.

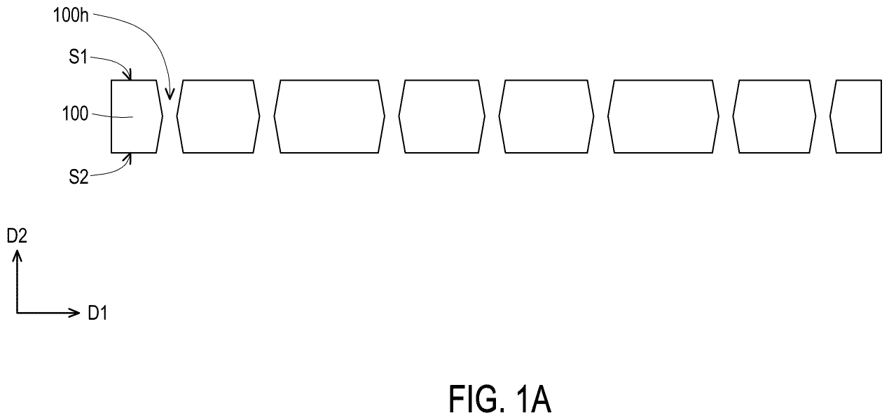

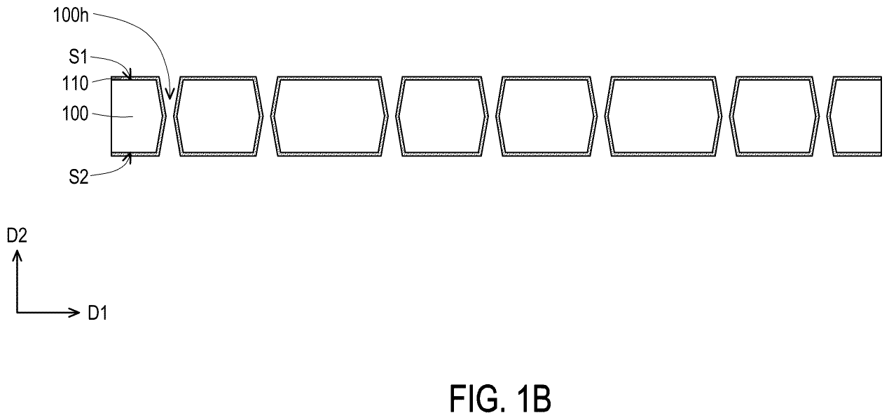

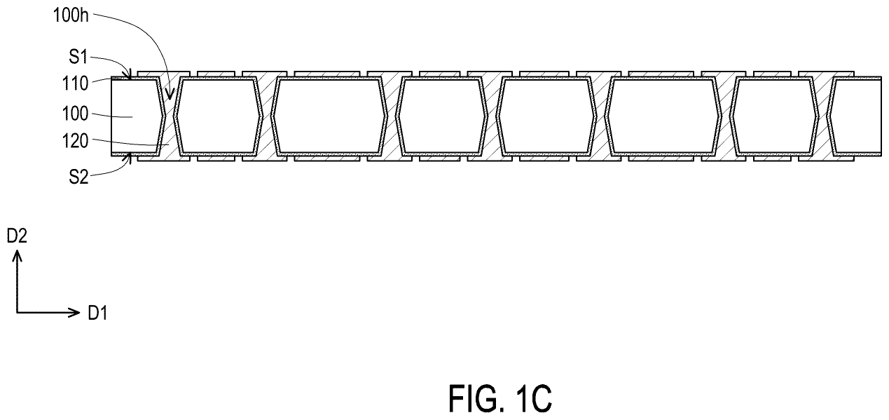

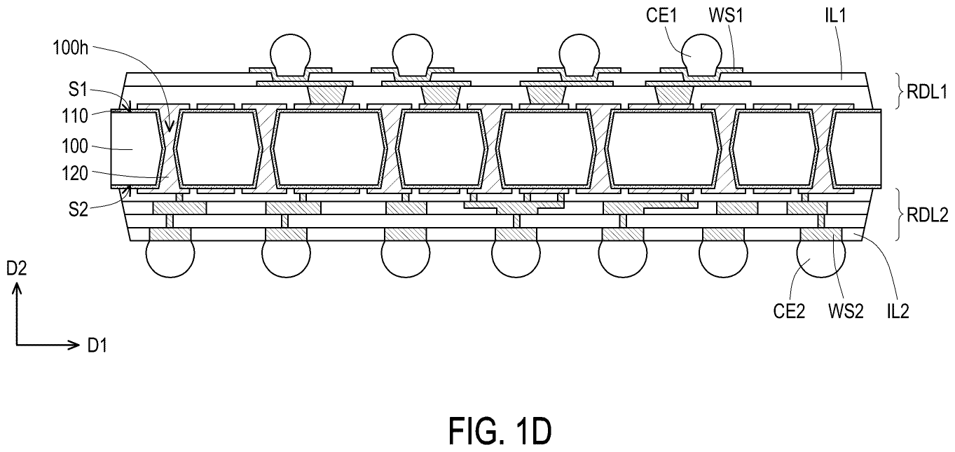

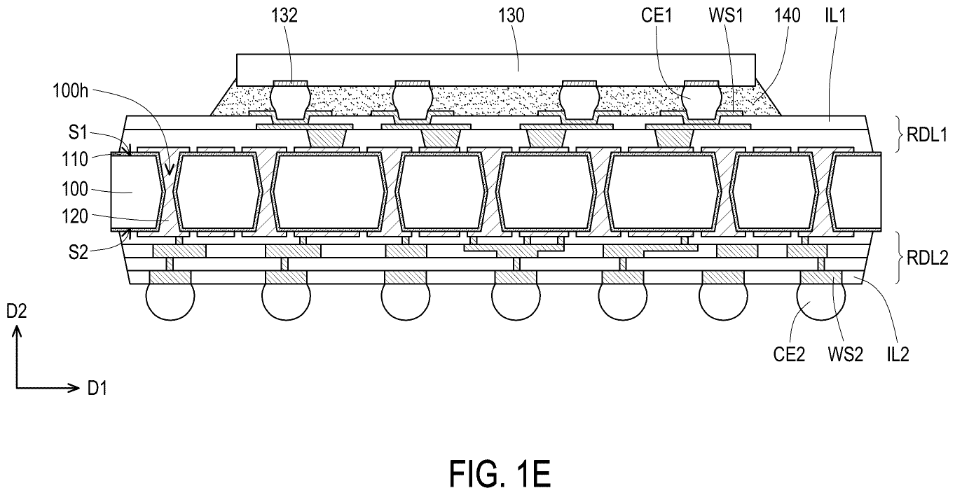

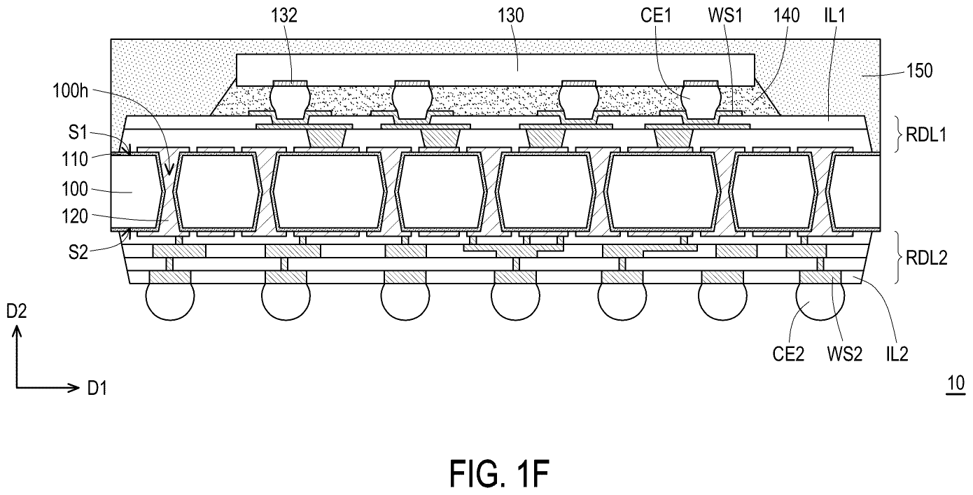

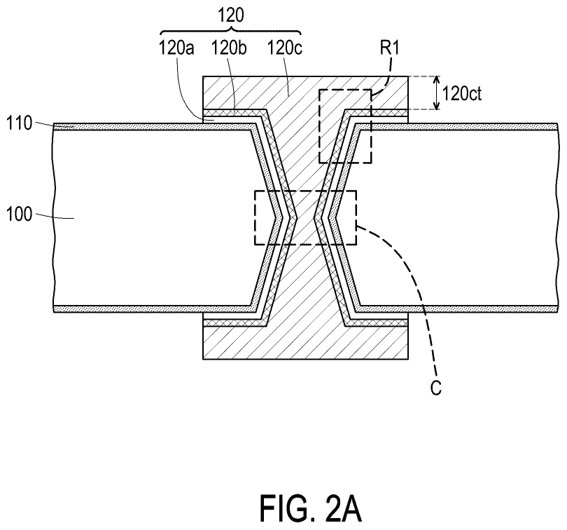

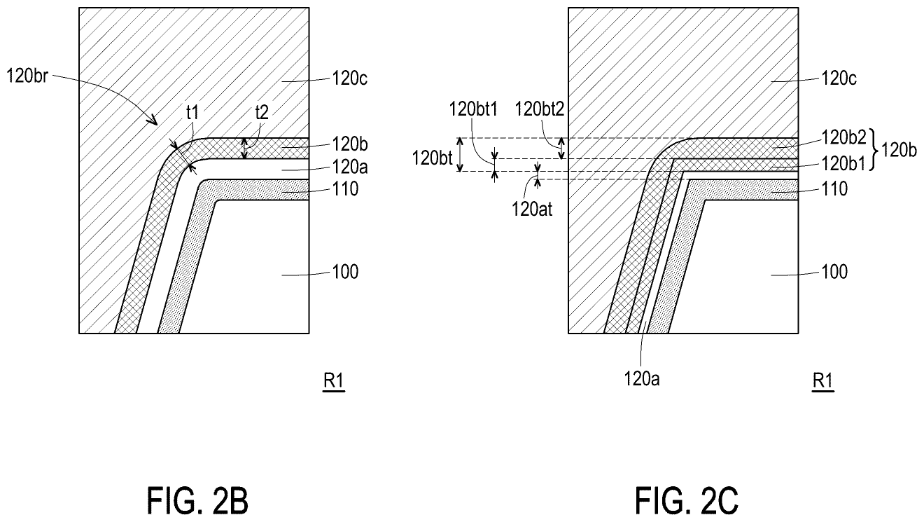

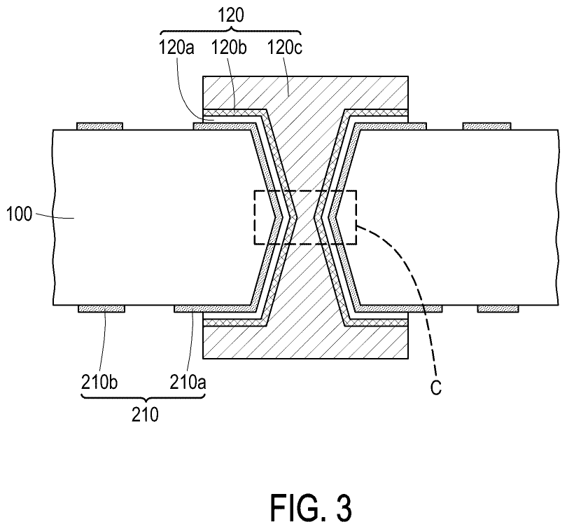

FIG. 1A to FIG. 1F are cross-sectional schematic views of a manufacturing method of an electronic device according to an embodiment of the present disclosure. FIG. 2A is an enlarged view of a conductive via in FIG. 1C according to an embodiment. FIG. 2B is an enlarged view of a region R1 in FIG. 2A according to an embodiment. FIG. 2C is an enlarged view of a region R1 in FIG. 2A according to another embodiment. FIGS. 3 to 8 are enlarged schematic views respectively for the conductive via in FIG. 1C according to different embodiments.

In some embodiments, a manufacturing method of an electronic device (such as the electronic device 10 shown in FIG. 1F) may include following steps.

First, referring to FIG. 1A, a substrate 100 is provided. The substrate 100 has a first surface S1 and a second surface S2 opposite to the first surface S1. The substrate 100 may include polyimide, glass, silicon, or other suitable materials for the substrate. In some embodiments, the substrate 100 may be a glass substrate. The coefficient of thermal expansion of the substrate 100 may be greater than or equal to 3 ppm/° C. and less than or equal to 8 ppm/° C. In some embodiments, the size of the substrate 100 may be at least greater than or equal to 10 mm*10 mm. In some embodiments, the thickness of the substrate 100 may be at least greater than or equal to 30 μm. In some embodiments, the substrate 100 may be used to support other elements, but is not limited thereto.

Next, a via hole 100h is formed in the substrate 100. The via hole 100h penetrates through the substrate 100 and has a sidewall connecting the first surface S1 and the second surface S2. In some embodiments, the via hole 100h may be formed by performing drilling processes, etching processes, or combinations thereof on the substrate 100. For example, a laser drill process may be performed on the first surface S1 and the second surface S2 of the substrate 100 to form the via hole 100h, but is not limited thereto. In other embodiments, the via hole 100h may be formed in the substrate 100 through modification treatment processes (e.g., laser modification processes) and etching processes.

Then, referring to FIG. 1B, a buffer layer 110 is formed on the substrate 100. The buffer layer 110 is disposed on a partial surface of the substrate 100 and on the sidewall of the via hole 100h. In some embodiments, the buffer layer 110 may be beneficial to alleviate cracking of the substrate 100 caused by the stress, but is not limited thereto. For example, the buffer layer 110 may repair defects (e.g., micro cracks) generated in a process of forming the via hole 100h in the substrate 100 through the aforementioned modification treatment processes (e.g., laser modification processes) and etching processes. In other embodiments, in the case where the substrate 100 is a glass substrate for example, the buffer layer 110 may alleviate the difference in coefficient of thermal expansion (CTE) between the substrate 100 and the conductive layer (e.g., the conductive via 120 shown in FIG. 1C) subsequently formed in the via hole 100h, so as to improve the adhesion of the conductive layer formed in the via hole 100h or to alleviate the stress applied to the substrate 100. In this embodiment, the buffer layer 110 is at least disposed on the sidewall of the via hole 100h and extends to a portion of the first surface S1 of the substrate 100 and a portion of the second surface S2 of the substrate 100. For example, the buffer layer 110 is at least disposed on the sidewall of the via hole 100h and extends to portions of the first surface S1 and the second surface S2 adjacent to the periphery of the via hole 100h.

The buffer layer 110 may include organic materials such as polyimide (PI), parylene, benzocyclobutene (BCB), epoxy resin, polycarbonate (PC), polyethylene terephthalate (PET), or polyethylene naphthalate (PEN). The toughness of the buffer layer 110 may be 0.1 kJ/m² to 100 KJ/m². The thickness of the buffer layer 110 may be greater than or equal to 0.01 μm and less than or equal to 10 μm. The ratio of the thickness of the buffer layer 110 to the diameter of the via hole 100h may be greater than or equal to 0.02 and less than or equal to 0.2. According to some embodiments, the thickness of the substrate 100 may be greater than or equal to 40 μm and less than or equal to 800 μm.

Subsequently, referring to FIG. 1C, a conductive via 120 is formed in the via hole 100h. In some embodiments, the conductive via 120 may be formed through, for example, an electroplating process, a chemical vapor deposition (CVD) process, a sputtering process, an atomic layer deposition (ALD) process, a resistance heating evaporation process, an electron beam evaporation process, other suitable deposition methods, or a combination of the aforementioned.

In some embodiments, referring to FIG. 1C, FIG. 2A, and FIG. 2B simultaneously, the conductive via 120 may include a passivation layer 120a disposed on the buffer layer 110, a conductive layer 120b disposed on the passivation layer 120a, and a conductive layer 120c disposed on the conductive layer 120b. The passivation layer 120a may prevent the surface oxidation, so that the conductive layer 120b formed on the passivation layer 120a can be well adhered to the passivation layer 120a, and thus the conductive layer 120c disposed on the conductive layer 120b can be well filled into the via hole 100h that penetrates the substrate 100. This may be beneficial to improve the aforementioned issues caused by the high aspect ratio, and thus enhancing the reliability of the electronic device.

The passivation layer 120a may include materials such as titanium nitride (TiN) or other nitrogen-containing conductive materials, but is not limited thereto. The thickness of the passivation layer 120a may be greater than or equal to 100 nm and less than or equal to 500 nm. In some embodiments, the passivation layer 120a may be formed through, for example, an ALD processes, but is not limited thereto. According to some embodiments, the coefficient of thermal expansion (CTE) of the passivation layer 120a may be greater than or equal to 5 ppm/20 C. and less than or equal to 10 ppm/° C. The Young's modulus of the passivation layer 120a may be between 230 GPa and 280 GPa.

The conductive layer 120b may include materials such as titanium (Ti), copper (Cu), tantalum (Ta), tungsten (W), graphene, or other suitable conductive materials. The conductive layer 120b may be served as a seed layer and may be, for example, a single-layer structure (as shown in FIG. 2B) or a composite layer structure with multiple sub-layers formed by stacking different materials (as shown in FIG. 2C). For example, as shown in FIG. 2C, the conductive layer 120b may be formed as a composite layer structure including a first layer 120b1 and a second layer 120b2 disposed on the first layer 120b1. In some embodiments, the first layer 120b1 may be, for example, a titanium layer, and the second layer 120b2 may be, for example, a copper layer, but is not limited thereto. In some embodiments, the conductive layer 120b may be formed through, for example, a CVD process, a sputtering process, an ALD process, other suitable deposition methods, or a combination of the aforementioned processes. For example, in the case where the thickness 120bt2 of the second layer 120b2 is greater than the thickness 120bt1 of the first layer 120b1, the first layer 120b1 may be formed, for example, by using an ALD process, and the second layer 120b2 may be formed, for example, by using a sputtering process, but is not limited thereto.

The conductive layer 120c may include materials such as copper (Cu), aluminum (Al), silver (Ag), graphene, or other suitable conductive materials. In some embodiments, the conductive layer 120c may be formed by using the conductive layer 120b as a seed layer and being grown thereon through an electroplating process.

In some embodiments, the resistivity of the passivation layer 120a may be greater than the resistivity of the conductive layer 120b. In some embodiments, the resistivity of the passivation layer 120a may be greater than the resistivity of the conductive layer 120c. For example, from an aspect of the material, in the case where the passivation layer 120a is a titanium nitride layer, the conductive layer 120b is a titanium layer, and the conductive layer 120c is a copper layer, the resistivity of the passivation layer 120a may be greater than or equal to 1.43Ω·m and less than or equal to 3.33Ω·m, the resistivity of the conductive layer 120b may be greater than or equal to 3.5×10⁻⁷Ω·m and less than or equal to 4.5×10⁻⁷Ω·m (e.g., 4.2×10⁻⁷Ω·m), and the resistivity of the conductive layer 120c may be greater than or equal to 1.5×10⁻⁸Ω·m and less than or equal to 2.5×10⁻⁸Ω·m (e.g., 1.678×10⁻⁸Ω·m). From an aspect of the thickness of the layer, even if the conductive layer 120b and the conductive layer 120c are formed of the same material (e.g., copper), the conductive layer 120c may have a lower resistivity than the conductive layer 120b due to the thickness of the conductive layer 120c is greater than the thickness of the conductive layer 120b. In some embodiments, the thickness of the passivation layer 120a (e.g., the thickness 120at shown in FIG. 2C) may be less than the thickness of the conductive layer 120b (e.g., the thickness 120bt shown in FIG. 2C) and the thickness of the second conductive layer 120c (e.g., the thickness 120ct shown in FIG. 2A). According to some embodiments, the thickness of the conductive layer 120b may be greater than or equal to 800 nm and less than or equal to 1500 nm. Through the design of the aforementioned layers, the risk of cracking in the substrate 100 may be reduced or the impact on electrical properties may be reduced, but is not limited thereto. According to some embodiments, the resistivity may be measured through a contact detection method or a non-contact detection method, but is not limited thereto.

In some embodiments, the bonding strength between the passivation layer 120a and the substrate 100 may be greater than the bonding strength between the conductive layer 120b and the substrate 100. In some embodiments, the bonding strength between the passivation layer 120a and the buffer layer 110 may be greater than the bonding strength between the conductive layer 120b and the buffer layer 110. For example, the magnitude of the bonding strength may be detected through a universal testing machine or a tensile testing machine. For example, a test may be conducted after depositing a passivation layer 120a with an area of 1 cm*1 cm on the buffer layer 110, but the method to the test is not limited thereto.

In some embodiments, as shown in FIG. 2A, before forming the conductive layer 120c, a surface treatment may be performed on the conductive layer 120b (e.g., performing a surface treatment through an etching or plasma process) to remove protrusions formed by the conductive layer 120b at the corner where the sidewall of the via hole 100h connects the first surface S1 and the second surface S2. This may allow the conductive layer 120b to have a relatively uniform thickness, and may allow the conductive layer 120c subsequently formed on the conductive layer 120b to be well formed in the via hole 100h. In this embodiment, with reference to FIG. 1C and FIG. 2B, the corner of the via hole 100h of the substrate 100 may have an arched corner, the buffer layer 110 and the passivation layer 120a may have an arched corner corresponding to the corner of the via hole 100h accordingly, and the conductive layer 120b may have an arched corner 120br at the corner where the sidewall of the via hole 100h connects the first surface S1 and the second surface S2. In some embodiments, the conductive layer 120b may have a first thickness t1 at the arched corner, the conductive layer 120b may have a second thickness t2 on the first surface S1, and the first thickness t1 is different from the second thickness t2. In some embodiments, the ratio of the first thickness to the second thickness may be greater than or equal to 0.3 and less than or equal to 0.8. Through the above design, the risk of cracking in the layer at the corner may be reduced, but it is not limited thereto.

In some embodiments, as shown in FIG. 2A, the buffer layer 110 may be a continuous layer. In other embodiments, as shown in FIG. 3, the buffer layer 210 may include a first portion 210a and a second portion 210b spaced apart from the first portion 210a. The first portion 210a of the buffer layer 210 may be disposed on the sidewall of the via hole 100h and may be a continuous layer, and the second portion 210b of the buffer layer 210 may be disposed on at least one of the first surface S1 and the second surface S2 of the substrate 100 and may be spaced apart from the first portion 210a of the buffer layer 210.

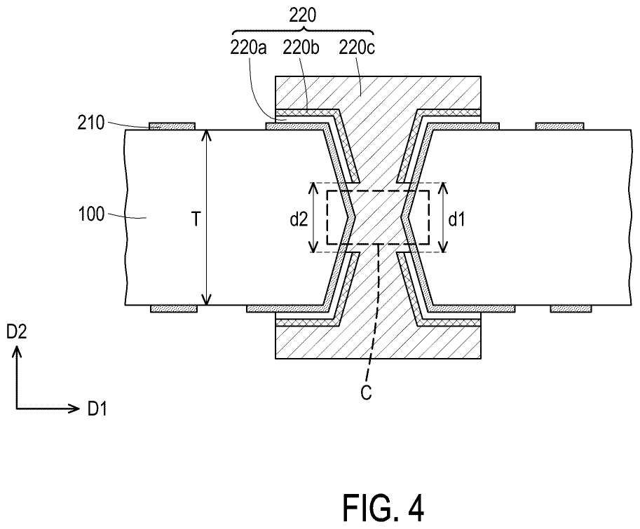

In some embodiments, as shown in FIG. 4, the passivation layer 220a may include a first portion extending from the first surface S1 of the substrate 100 to the sidewall of the via hole 100h and a second portion extending from the second surface S2 of the substrate 100 to the sidewall of the via hole 100h. The first portion and the second portion of the passivation layer 220a may be spaced apart by a first gap d1 at the center position C of the via hole 100h. In this embodiment, the first portion and the second portion of the passivation layer 220a may be spaced apart by the first gap d1 in the via hole 100h in the normal direction of the substrate 100 (e.g., the direction D2 shown in FIG. 1C). The first gap d1 may be less than or equal to half of the thickness T of the substrate 100. According to some embodiments, the center position C may be at a position spaced 0.3*T to 0.7*T from the first surface S1 or in the range of 0.4*T to 0.6*T.

In some embodiments, as shown in FIG. 4, the conductive layer 220b may include a first portion extending from the first surface S1 of the substrate 100 to the sidewall of the via hole 100h and a second portion extending from the second surface S2 of the substrate 100 to the sidewall of the via hole 100h. The first portion and the second portion of the conductive layer 220b may be spaced apart by a second gap at the center position C of the via hole 100h. In this embodiment, the first portion and the second portion of the conductive layer 220b may be spaced apart by the second gap d2 in the via hole 100h in the normal direction of the substrate 100 (e.g., the direction D2 shown in FIG. 1C). The second gap d2 may be less than or equal to half of the thickness T of the substrate 100.

In the embodiment shown in FIG. 4, although the passivation layer 220a and the conductive layer 220b formed on the passivation layer 220a, respectively extending from the first surface S1 and the second surface S2 of the substrate 100 into the via hole 100h, are discontinuous at the center position C of the via hole 100h, the conductive layer 220c formed on the conductive layer 220b may still be able to fill the via hole 100h well since the first gap d1 and the second gap d2 are less than half of the thickness T of the substrate 100, and thus the probability of voids generated in the via hole 100h can be reduced. In other words, according to some embodiments, the maximum distance or diameter of the voids in the via hole 100h may be less than ¼ of the thickness T of the substrate 100, ensuring that the conductive via 220 including the passivation layer 220a, the conductive layer 220b and the conductive layer 220c still has good reliability.

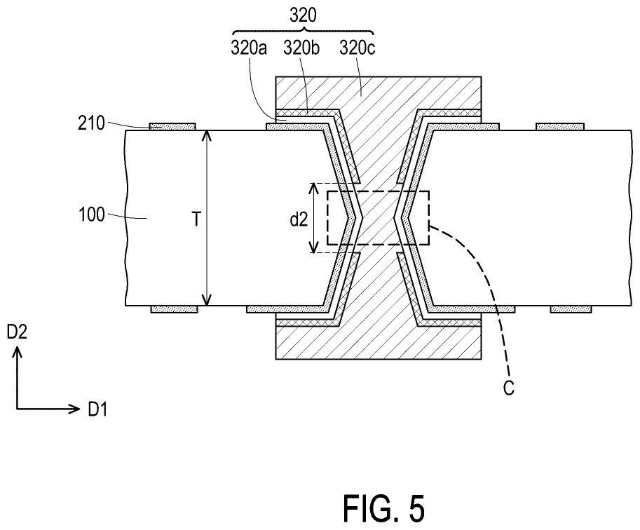

In some embodiments, at least one of the passivation layer 320a and the conductive layer 320b may be a continuous layer. For example, as shown in FIG. 5, the passivation layer 320a may extend from the first surface S1 and the second surface S2 of the substrate 100 into the via hole 100h, respectively, and may be continuous at the center position C of the via hole 100h. The conductive layer 320b may include a first portion extending from the first surface S1 of the substrate 100 to the sidewall of the via hole 100h and a second portion extending from the second surface S2 of the substrate 100 to the sidewall of the via hole 100h. The first portion and the second portion of the conductive layer 320b may be spaced apart by a second gap d2 at the center position C of the via hole 100h. That is, the conductive layer 320b may extend from the first surface S1 and the second surface S2 of the substrate 100 into the via hole 100h, respectively, and may be discontinuous at the center position C of the via hole 100h. The conductive layer 320c formed on the conductive layer 320b may still be able to fill the via hole 100h well since the second gap d2 is less than half of the thickness T of the substrate 100 and the conductive passivation layer 320a is still at the center position C of the via hole 100h, and thus the probability of voids generated in the via hole 100h can be reduced, ensuring that the conductive via 320 including the passivation layer 320a, the conductive layer 320b and the conductive layer 320c still has good reliability.

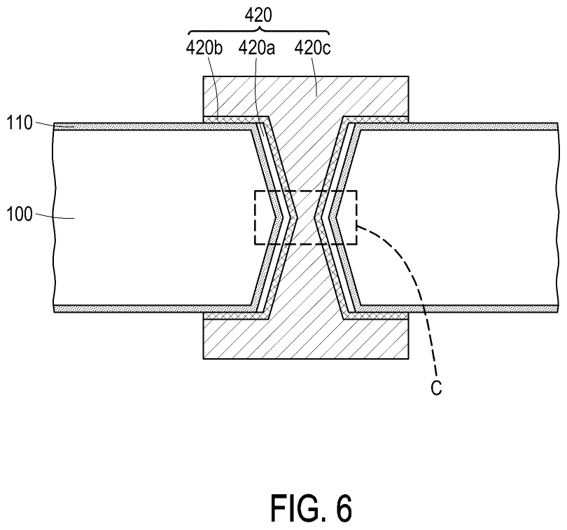

In some embodiments, as shown in FIG. 6, the passivation layer 420a may be disposed on the sidewall of the via hole 100h without extending to the first surface S1 and the second surface S2 of the substrate 100. The conductive layer 420b may extend from the first surface S1 and the second surface S2 of the substrate 100 into the via hole 100h, respectively, and may be continuous at the center position C of the via hole 100h. In this embodiment, the portions of the conductive layer 420b disposed on the first surface S1 and the second surface S2 of the substrate 100 may directly contact the buffer layer 110. The conductive layer 420c formed on the conductive layer 420b may still be able to fill the via hole 100h well since the passivation layer 420a and the conductive layer 420b disposed on the passivation layer 420a are continuous in the via hole 100h (especially continuous at the center position C of the via hole 100h), and thus the probability of voids generated in the via hole 100h can be reduced, ensuring that the conductive via 420 including the passivation layer 420a, the conductive layer 420b, and the conductive layer 420c still has good reliability.

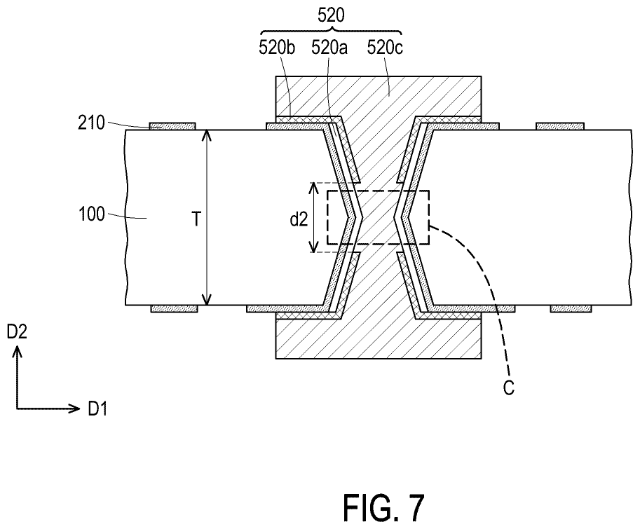

In some embodiments, as shown in FIG. 7, the passivation layer 520a may be disposed on the sidewall of the via hole 100h without extending to the first surface S1 and the second surface S2 of the substrate 100. The conductive layer 520b may include a first portion extending from the first surface S1 of the substrate 100 to the sidewall of the via hole 100h and a second portion extending from the second surface S2 of the substrate 100 to the sidewall of the via hole 100h. The first portion and the second portion of the conductive layer 520b may be separated by a second gap d2 at the center position C of the via hole 100h. That is, the conductive layer 520b may extend from the first surface S1 and the second surface S2 of the substrate 100 into the via hole 100h, respectively, and may be discontinuous at the center position C of the via hole 100h. The conductive layer 520c formed on the conductive layer 520b may still be able to fill the via hole 100h well since the second gap d2 is less than half of the thickness T of the substrate 100 and the conductive passivation layer 520a is still at the center position C of the via hole 100h, and thus the probability of voids generated in the via hole 100h can be reduced, ensuring that the conductive via 520 including the passivation layer 520a, the conductive layer 520b, and the conductive layer 520c still has good reliability.

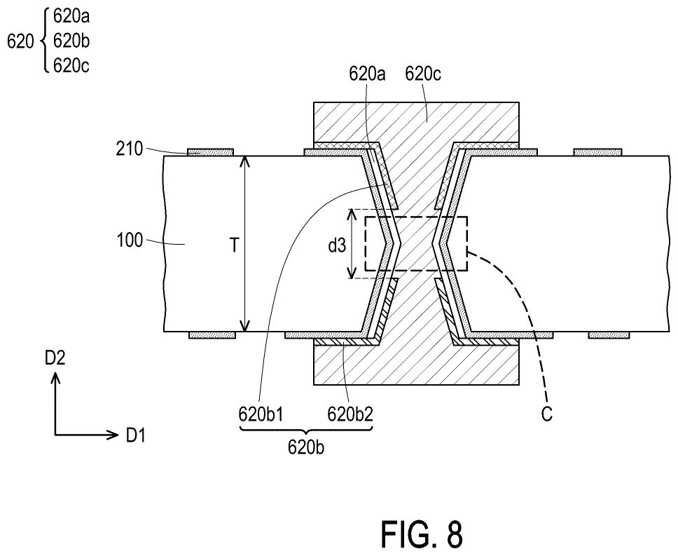

In some embodiments, as shown in FIG. 8, the passivation layer 620a may be disposed on the sidewall of the via hole 100h without extending to the first surface S1 and the second surface S2 of the substrate 100. The conductive layer 620b may include a first portion 620b1 extending from the first surface S1 of the substrate 100 to the sidewall of the via hole 100h and a second portion 620b2 extending from the second surface S2 of the substrate 100 to the sidewall of the via hole 100h. In this embodiment, the first portion 620b1 and the second portion 620b2 of the conductive layer 620b may be formed by different materials and/or different processes and may be separated by a third gap d3 at the center position C of the via hole 100h. That is, the first portion 620b1 and the second portion 620b2 of the conductive layer 620b may extend from the first surface S1 and the second surface S2 of the substrate 100 into the via hole 100h, respectively, and may be discontinuous at the center position C of the via hole 100h. The conductive layer 620c formed on the conductive layer 620b may still be able to fill the via hole 100h well since the third gap d3 is less than half of the thickness T of the substrate 100 and the conductive passivation layer 620a is still at the center position C of the via hole 100h, and thus the probability of voids generated in the via hole 100h can be reduced, ensuring that the conductive via 620 including the passivation layer 620a, the conductive layer 620b, and the conductive layer 620c still has good reliability.

Next, please return to FIG. 1C and refer to FIG. 1D simultaneously, redistribution structures RDL1 and RDL2 electrically connected to the conductive via 120 are formed on the first surface S1 and the second surface S2 of the substrate 100 respectively. The redistribution structures RDL1 and RDL2 may be electrically connected to chips or electronic units (e.g., the electronic unit 130 shown in FIG. 1E) through contact elements CE1, CE2 or other connection elements. The redistribution structure RDL1 may include an insulation layer IL1 and a wiring structure WS1. The redistribution structure RDL2 may include an insulation layer IL2 and a wiring structure WS2. The insulation layers IL1 and IL2 may include a plurality of insulation layers alternately stacked along the direction D2. The wiring structures WS1 and WS2 may include a plurality of conductive patterns formed in the insulation layers IL1 and IL2 and alternately stacked along the direction D2 and a conductive via connecting the conductive patterns. The redistribution structures RDL1 and RDL2 may be able to redistribute the wirings and/or to increase the fan-out area of the wirings, or different electronic elements may be electrically connected to each other through the redistribution structures. The method for forming the redistribution structures may include providing a stack of at least one insulation layer and at least one conductive layer and may include processes such as a photolithography process, an etching process, a surface treatment, a laser process, and an electroplating process. The surface treatment includes roughening the surface of the insulation layer or the conductive layer to enhance its adhesion ability. Alternatively, the redistribution structures RDL1 and RDL2 may be used as a substrate for the electrical interface wiring between one connection and another connection. The purpose of the redistribution structure is to extend the connections to wider gaps or redistribute the connections to another connection with different gaps. The insulation layers IL1 and IL2 may include polyimide (PI), photosensitive polyimide (PSPI), polybenzoxazole (PBO), benzocyclobutene (BCB), epoxy resin, Ajinomoto Build-up Film (ABF), silicon oxide (SiOx), silicon nitride (SiNx), any other suitable insulating materials or combinations thereof, but are not limited thereto. The wiring structures WS1 and WS2 may include any suitable conductive materials, such as copper, titanium, nickel, combinations or alloys of the above materials, but are not limited thereto. In this embodiment, the contact elements CE1, CE2 may include solder balls. The materials of the contact elements CE1, CE2 may include tin-silver (SnAg), tin, silver, nickel, gold, copper, gallium, chromium, conductive adhesive, or other suitable conductive materials, but are not limited thereto. In some embodiments, the thicknesses of the insulation layers IL1 and IL2 may be greater than the thickness of the buffer layer 110. In some embodiments, the thicknesses of the insulation layers IL1 and IL2 may be greater than or equal to 5 μm and less than or equal to 15 μm.

Then, please refer to FIG. 1E, an electronic unit 130 is provided. The electronic unit 130 may be disposed on the conductive via 120 (i.e., being disposed on the conductive layer 120c shown in FIG. 2A). The electronic unit 130 may be disposed on the redistribution structure RDL1 and electrically connected to the redistribution structure RDL1 through the contact element CE1.

The electronic unit 130 may include a chip, a diode, an antenna unit, a memory unit, a photonic integrated circuit (PIC) unit, a sensor, or a structure related to the semiconductor process. The electronic unit 130 may include a pad 132, wherein the pad 132 may be located on a side of the electronic unit 130. In an embodiment where the electronic unit is a chip, the side on which the pad 132 is located is the front side of the chip (also known as the active surface), while the other side (or surface) opposite to the front side (or active surface) of the chip is the back side (or back surface). In this embodiment, the number of pads 132 on different electronic units 130 may be the same or different. According to some embodiments, the sizes of the pads 132 on different electronic units 130 may be the same or different. The pad 132 may include any suitable conductive material, for example, copper (Cu), aluminum (Al), nickel (Ni), molybdenum (Mo), titanium (Ti), alloys or combinations of the above materials, or other suitable materials, but is not limited thereto.

Thereafter, as shown in FIG. 1E, an underfill 140 surrounding the contact element CE1 is provided between the electronic unit 130 and the redistribution structure RDL1, so as to enhance the reliability of the electronic device (e.g., the electronic device 10 shown in FIG. 1F). In this embodiment, “one element surrounding another element” may refer to the element being in contact with at least the side surface of the other element in the cross-sectional view. For example, as shown in FIG. 1E, the underfill 140 may be in contact with the side surface of the contact element CE1.

Then, referring to FIG. 1F, an encapsulating layer 150 surrounding the electronic unit 130 and the redistribution structure RDL1 is provided on the first surface S1 of the substrate 100. The encapsulating layer 150 may protect the electronic unit 130 from external moisture, thereby improving the reliability of the electronic unit 130. The encapsulating layer 150 may include any suitable encapsulating material, for example, epoxy molding compound (EMC), but is not limited thereto.

The following will describe the electronic device 10 with reference to FIG. 1F and FIG. 2A. The electronic device 10 shown in FIG. 1F may be formed by the method described above, but is not limited thereto. The electronic device 10 may include a substrate 100, a via hole 100h, a buffer layer 110, a passivation layer 120a, a first conductive layer 120b, a second conductive layer 120c, and an electronic unit 130. The substrate 100 has a first surface S1 and a second surface S2 opposite to the first surface S1. The via hole 100h penetrates through the substrate 100 and has a sidewall connecting the first surface S1 and the second surface S2. The buffer layer 110 is disposed on the substrate 100 and the sidewall of the via hole 100h. The passivation layer 120a is disposed on the buffer layer 110, wherein the passivation layer 120a contains at least nitrogen. The first conductive layer 120b is disposed on the passivation layer 120a. The second conductive layer 120c is disposed on the first conductive layer 120b. The electronic unit 130 is disposed on the second conductive layer 120c.

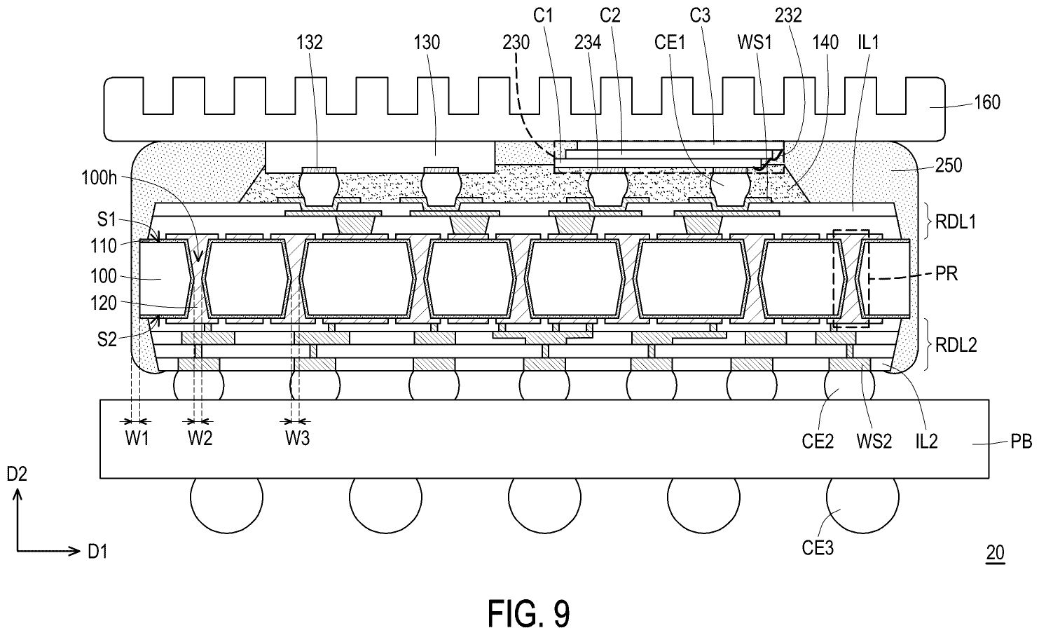

FIG. 9 is a cross-sectional schematic view of an electronic device according to another embodiment of the present disclosure. The electronic device 20 shown in FIG. 9 is similar to the electronic device 10 shown in FIG. 1F. The main differences therebetween are that the electronic device 20 further includes an electronic unit 230 and a heat dissipation element 160, and the encapsulating layer 250 of the electronic device 20 surrounds the outer sidewall of the substrate 100. Other identical or similar elements are represented by the same or similar reference numerals, and will not be repeated hereinafter.

As shown in FIG. 9, the electronic device 20 may include the electronic unit 130 and the electronic unit 230. The electronic unit 130 and the electronic unit 230 may be disposed on the redistribution structure RDL1 and may be electrically connected to the redistribution structure RDL1 through the contact element CE1. The electronic unit 230 may include a plurality of chips C1, C2 and C3 stacked on each other in the direction D2. The chip C1, the chip C2 and the chip C3 may be electrically connected to each other through a wire bonding. For example, the chip C1, the chip C2 and the chip C3 may be electrically connected to each other through conductive wires 232. In some embodiments, the electronic unit 230 may be electrically connected to the contact element CE1 through a pad 234 disposed between the contact element CE1 and the electronic unit 230. The conductive wire 232 may include any suitable conductive material. The pad 234 may include any suitable conductive material, for example, copper (Cu), aluminum (Al), nickel (Ni), molybdenum (Mo), titanium (Ti), alloys or combinations of the above materials, or other suitable materials, but is not limited thereto.

In some embodiments, the electronic device 20 may include an encapsulating layer 250 surrounding the substrate 100 and the electronic units 130 and 230. The encapsulating layer 250 may surround the outer sidewall of the substrate 100 to protect the substrate 100, thereby the concerns of cracking in the substrate 100 can be avoided and the reliability of the electronic device 20 can be improved accordingly. In this embodiment, the encapsulating layer 250 may cover a portion of the top surface of the redistribution structure RDL2 (e.g., the portion at the corner).

In some embodiments, the electronic device 20 may include a heat dissipation element 160 (e.g., a heat dissipation sheet). The heat dissipation element 160 may contact the back sides of the electronic unit 130 and the electronic unit 230, so that the heat generated by the electronic unit 130 and the electronic unit 230 during operation may be dissipated through the heat dissipation element 160. In some embodiments, the back sides of the electronic unit 130 and the electronic unit 230 may be exposed from the encapsulating layer 250 through a grinding process. In this embodiment, the top surface of the encapsulating layer 250 may be coplanar with the back sides of the electronic unit 130 and the electronic unit 230.

In some embodiments, the substrate 100 of the electronic device 20 may include an outer sidewall facing the encapsulating layer 250 and connecting the first surface S1 and the second surface S2, wherein the thickness of the encapsulating layer 250 disposed on the outer sidewall of the substrate 100 is W1, and the width at the center of the via hole 100h offset from the electronic unit 130 or the electronic unit 230 in the normal direction of the substrate 100 (e.g., direction D2) is W2, and 2*W2≤W1≤10*W2. In this way, the encapsulating layer 250 may meet the aforementioned requirement of protecting the substrate 100, and can avoid the problems caused by the shrinkage stress due to the excessive thickness of the encapsulating layer 250 on the outer sidewall of the substrate 100 (e.g., W1 shown in FIG. 9) as well. In this embodiment, W1 and W2 shown in FIG. 9 may be, for example, the sizes measured in the horizontal direction (e.g., direction D1).

In some embodiments, the width at the center of the via hole 100h overlapping with the electronic unit 130 or the electronic unit 230 in the normal direction of the substrate 100 (e.g., direction D2) is W3, and W3<W2. In this way, the conductive layer in the via hole 100h offset from the electronic unit 130 or the electronic unit 230, or the conductive layer in the via hole 100h located in the peripheral region of the substrate 100 (e.g., region PR shown in FIG. 9) may have a wider design, so that the effect of heat dissipation of the electronic device 20 can be improved. In some embodiments, the conductive layer in the via hole 100h offset from the electronic unit 130 or the electronic unit 230 may be electrically floating or connected to a ground signal. According to some embodiments, the thermal conductivity coefficient of the contact element CE2 may be different from the thermal conductivity coefficient of the contact element CE1. F or example, the thermal conductivity coefficient of the contact element CE2 may be greater than the thermal conductivity coefficient of the contact element CE1. According to some embodiments, the thermal conductivity coefficient of the contact element CE2 overlapping with the conductive layer in the via hole 100h offset from the electronic unit 130 or the electronic unit 230 may be different from the thermal conductivity coefficient of the contact element CE2 overlapping with the conductive layer in the via hole 100h overlapping with the electronic unit 130 or the electronic unit 230. For example, the thermal conductivity coefficient of the contact element CE2 overlapping with the conductive layer offset from the electronic unit 130 or the electronic unit 230 may be greater than the thermal conductivity coefficient of the contact element CE2 overlapping with the conductive layer in the via hole 100h overlapping with the electronic unit 130 or the electronic unit 230. In some embodiments, the electronic device 20 may include an external element PB, which may be electrically connected to the electronic unit 130 or the electronic unit 230 through the contact element CE2, wherein the external element PB may include an IC carrier, a PCB circuit board, a through-silicon substrate, or other suitable external elements. In some embodiments, the electronic device 20 may include a contact element CE3 disposed on the side of the external element PB opposite to the contact element CE2. The material of the contact element CE3 may be the same as or different from that of the contact element CE1 or that of the contact element CE2. The gap between two adjacent contact elements CE3 is greater than the gap between two adjacent contact elements CE2. The electronic device 20 may be bonded to other electronic devices or external elements through the contact element CE3, wherein the substrate 100 may serve as an interposer, but is not limited thereto.

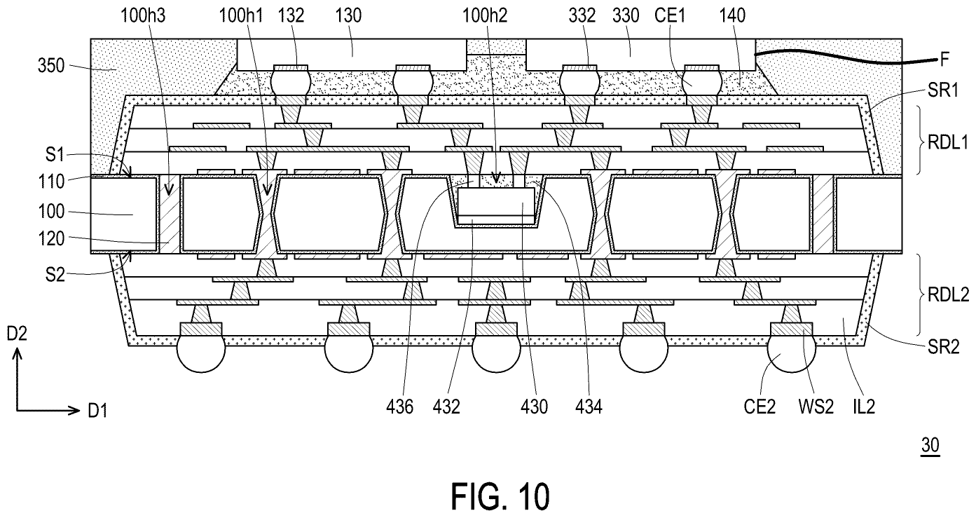

FIG. 10 is a cross-sectional schematic view of an electronic device according to yet another embodiment of the present disclosure. The electronic device 30 shown in FIG. 10 is similar to the electronic device 10 shown in FIG. 1F, and the main differences are that the electronic device 30 further includes electronic units 330 and 430 and a heat dissipation element 1000, and the redistribution structure RDL1 and the redistribution structure RDL2 of the electronic device 30 are covered by solder resist layers SR1 and SR2, respectively. Other identical or similar elements are represented by the same or similar reference numerals, and will not be repeated hereinafter.

In some embodiments, as shown in FIG. 10, the electronic device 30 may include electronic units 130 and 330 disposed on the redistribution structure RDL1. The electronic units 130 and 330 may be electrically connected to the redistribution structure RDL1 through contact elements CE1. The electronic unit 330 may include a pad 332. The electronic unit 330 may be electrically connected to the contact element CE1 through the pad 332. The pad 332 may include any suitable conductive material, for example, copper (Cu), aluminum (Al), nickel (Ni), molybdenum (Mo), titanium (Ti), alloys or combinations of the above materials, or other suitable materials, but is not limited thereto. In some embodiments, the electronic unit 330 may be a photonic integrated circuit (PIC) connected to a fiber F, but is not limited thereto.

In some embodiments, as shown in FIG. 10, the substrate 100 of the electronic device 30 may include a via hole 100h1 in which the conductive via 120 as described above is formed, a blind hole 100h2 in which the electronic unit 430 is disposed, and a via hole 100h3 in which the heat dissipation element 1000 is formed. The electronic unit 430 may include a surface mount device (SMD). In some embodiments, the electronic unit 430 may include elements such as large scale integrated circuits (LSI circuits) chips, integrated circuit (IC) chips, connectors, passive elements, or other suitable electronic elements. The electronic unit 430 may be attached to the bottom surface of the blind hole 100h2 through an adhesive member 432. The electronic unit 430 may be electrically connected to the redistribution structure RDL1 through a connection member 436. An underfill 434 may fill the blind hole 100h2 to surround the electronic unit 430. The adhesive member 432 may include any suitable adhesive material, for example, epoxy resin, die attach film (DAF), other suitable adhesive materials, or combinations thereof, but is not limited thereto. The connection member 436 may include any suitable conductive material, for example, copper (Cu), aluminum (Al), nickel (Ni), molybdenum (Mo), titanium (Ti), alloys or combinations of the above materials, or other suitable materials, but is not limited thereto.

The heat dissipation element 1000 is formed in the substrate 100 near its outer sidewall. The heat dissipation element 1000 may be electrically floating, for example, the heat dissipation element 1000 may not be electrically connected to the electronic unit 130, the electronic unit 330, or the electronic unit 430. In this embodiment, the heat dissipation element 1000 may be a conductive pillar formed in the via hole 100h3 of the substrate 100. The heat dissipation element 1000 may include any suitable conductive material.

In summary, in the embodiments of the present disclosure, the passivation layer, at least containing nitrogen, is disposed on the buffer layer, so as to prevent the surface oxidation, and thereby the first conductive layer disposed on the passivation layer can be well adhered to the passivation layer. As such, the second conductive layer disposed on the first conductive layer can be well filled into the via hole penetrating through the substrate without defects caused by the high aspect ratio, and thus the reliability of the electronic device can be improved.

The above embodiments are used to describe the technical solution of the disclosure and are not a limitation thereof. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

Although the embodiments of the disclosure and their advantages are disclosed as above, it should be understood that any person with ordinary skill in the art, without departing from the spirit and scope of the disclosure, may make changes, substitutions, and modifications, and features between the embodiments may be mixed and replaced at will to form other new embodiments. In addition, the scope of the disclosure is not limited to the manufacturing processes, machines, manufactures, material compositions, devices, methods, and steps in the specific embodiments described in the specification. Any person with ordinary skill in the art may understand the current or future development processes, machines, manufactures, material compositions, devices, methods, and steps from the content of the disclosure, which may all be adopted according to the disclosure as long as they may implement substantially the same function or obtain substantially the same result in an embodiment described here. Therefore, the scope of the disclosure includes the above manufacturing processes, machines, manufactures, material compositions, devices, methods, and steps. In addition, each claim constitutes an individual embodiment, and the scope of the disclosure also includes the combination of each claim and embodiment. The scope of the disclosure shall be subject to the scope defined by the following claims.

What is claimed is:

1. An electronic device, comprising:
a substrate having a first surface and a second surface opposite to the first surface;
a via hole penetrating through the substrate and having a sidewall connecting the first surface and the second surface;
a buffer layer disposed on the substrate and the sidewall of the via hole;
a passivation layer disposed on the buffer layer;
a first conductive layer disposed on the passivation layer;
a second conductive layer disposed on the first conductive layer; and
an electronic unit disposed on the second conductive layer,
wherein the passivation layer at least contains nitrogen.

2. The electronic device according to claim 1, wherein a resistivity of the passivation layer is greater than a resistivity of the first conductive layer.

3. The electronic device according to claim 1, wherein a resistivity of the first conductive layer is greater than a resistivity of the second conductive layer.

4. The electronic device according to claim 1, wherein a resistivity of the passivation layer is greater than a resistivity of the second conductive layer.

5. The electronic device according to claim 1, wherein the first conductive layer has an arched corner at the corner where the sidewall connects the first surface and the second surface.

6. The electronic device according to claim 5, wherein the first conductive layer has a first thickness at the arched corner, the first conductive layer has a second thickness on the first surface, and the first thickness is different from the second thickness.

7. The electronic device according to claim 6, wherein a ratio of the first thickness to the second thickness is 0.3 to 0.8.

8. The electronic device according to claim 1, wherein a thickness of the passivation layer is less than a thickness of the first conductive layer and a thickness of the second conductive layer.

9. The electronic device according to claim 1, wherein the buffer layer is a continuous layer.

10. The electronic device according to claim 1, wherein the buffer layer comprises a first portion and a second portion spaced apart from the first portion, the first portion of the buffer layer is disposed on the sidewall and is a continuous layer, and the second portion of the buffer layer is disposed on at least one of the first surface and the second surface of the substrate.

11. The electronic device according to claim 1, wherein at least one of the passivation layer and the first conductive layer is a continuous layer.

12. The electronic device according to claim 1, wherein the passivation layer comprises a first portion extending from the first surface of the substrate to the sidewall of the via hole and a second portion extending from the second surface of the substrate to the sidewall of the via hole, and the first portion and the second portion are spaced apart by a first gap at a center position of the via hole.

13. The electronic device according to claim 12, wherein the first gap is less than or equal to half of a thickness of the substrate.

14. The electronic device according to claim 1, wherein the first conductive layer comprises a first portion extending from the first surface of the substrate to the sidewall of the via hole and a second portion extending from the second surface of the substrate to the sidewall of the via hole, and the first portion and the second portion are spaced apart by a second gap at a center position of the via hole.

15. The electronic device according to claim 14, wherein the second gap is less than or equal to half of a thickness of the substrate.

16. The electronic device according to claim 1, further comprising:
a third conductive layer disposed on the passivation layer and extending from the second surface of the substrate to the sidewall of the via hole,
wherein the first conductive layer extends from the first surface of the substrate to the sidewall of the via hole and is spaced apart from the third conductive layer by a third gap, and the third gap is less than or equal to half of a thickness of the substrate.

17. The electronic device according to claim 1, wherein the passivation layer is disposed on the sidewall of the via hole, portions of the first conductive layer disposed on the first surface and the second surface of the substrate are in direct contact with the buffer layer.

18. The electronic device according to claim 1, wherein the first conductive layer comprises a first layer and a second layer disposed on the first layer, and a thickness of the second layer is greater than a thickness of the first layer.

19. The electronic device according to claim 1, further comprising:
an encapsulating layer surrounding the substrate and the electronic unit.

20. The electronic device according to claim 19, wherein the substrate comprises an outer sidewall facing the encapsulating layer and connecting the first surface and the second surface, a thickness of the encapsulating layer disposed on the outer sidewall of the substrate is W1, a width of the via hole at a center of the via hole in a thickness direction of the substrate is W2, and 2*W2≤W1≤10*W2.
